(19) United States
(12) Patent Application Publication
(10) Pub. No.: US 2010/0102323 A1
(43) Pub. Date: Apr. 29, 2010

(54) Directionally Annealed Silicon Film Having a (100)-Normal Crystallographical Orientation

(76) Inventors: Robert S. Sposili, Vancouver, WA (US); Apostolos T. Voutsas, Portland, OR (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(21) Appl. No.: 12/258,363

(22) Filed: Oct. 24, 2008

(51) Int. Cl. H01L 29/04; H01L 21/36

(52) U.S. Cl. 257/64; 438/487; 257/E29.004

(57) ABSTRACT

A method is provided for forming a directionally crystallized (100)-normal crystallographic orientation silicon (Si) film. The method provides a substrate including Si. An amorphous Si (a-Si) layer is formed overlying the substrate, and a silicon oxide cap layer is formed overlying the a-Si layer. In response to scanning a laser in a first direction along a top surface of the silicon oxide cap layer, the a-Si layer is transformed into a crystalline Si film having a (100)-normal crystallographic orientation, with crystal grains elongated in the first direction. That is, the crystalline Si film has grain boundaries between crystal grains, aligned in parallel with the first direction.

### BACKGROUND OF THE INVENTION

1. Field of the Invention

This invention generally relates to integrated circuit (IC) fabrication and, more particularly, to a process for forming silicon (Si) thin-films having a (100)-normal crystallographic orientation in a controlled direction.

2. Description of the Related Art

It is well established that TFT (thin-film transistor) performance correlates with the microstructural quality of the semiconductor material (typically silicon) on which the devices are fabricated. Perhaps the ideal material out of which to make silicon-based TFTs would be a thin film of monolithic (single-crystal) silicon, on an appropriate substrate, with (100) normal orientation. This structure would most closely emulate the nearly perfect bulk monolithic silicon used in integrated circuits (ICs). However, no viable method for creating such a material has yet been invented.

Various laser-irradiation schemes have been invented for creating a multitude of polycrystalline silicon microstructures on substrates such as glass. Recently, schemes have been developed involving the use of a CW (continuous-wave) laser to produce small- and medium-grain-sized equiaxed polycrystalline silicon films with a preferred (100)-normal crystallographic orientation. However, as of yet, no method has been revealed improving or modifying the microstructure of (100)-normal textured polycrystalline films.

It would be advantageous if a process existed for forming Si thin-film in (100)-normal crystallographic orientation, with a preferred (controlled) direction of grain elongation [i.e., directionally (laterally) crystallized microstructure].

### SUMMARY OF THE INVENTION

Described herein is a process to produce a directionally solidified, as opposed to equiaxed, polycrystalline silicon microstructure with a preferred (100)-normal crystallographic orientation. This process is a step closer towards monolithic single-crystal material and provides superior TFT performance, as compared with the previous technology. This process was discovered in the course of attempts to reduce the surface roughness of the laser-crystallized silicon films. As a result, the scheme provides the dual benefits of (1) reduced surface roughness and (2) superior microstructure [directional with (100)-normal crystallographic orientation].

Accordingly, a method is provided for forming a directionally crystallized (100)-normal crystallographic orientation Si film. The method provides a substrate including Si. An amorphous Si (a-Si) layer is formed overlying the substrate, and a silicon oxide cap layer is formed overlying the a-Si layer. In response to scanning a laser in a first direction along a top surface of the silicon oxide cap layer, the a-Si layer is transformed into a crystalline Si film having a (100)-normal crystallographic orientation, with crystal grains elongated in the first direction. That is, the crystalline Si film has grain boundaries between crystal grains, aligned in parallel with the first direction.

In one aspect, forming the a-Si layer includes forming an a-Si layer with pattern regions exposing portions of the substrate. Then, in addition to forming the silicon oxide cap layer overlying the a-Si layer, silicon oxide is formed in the a-Si layer pattern regions.

In another aspect, the a-Si layer is transformed into the crystalline Si film by completely melting the Si in response to laser annealing. Alternately, partially melted Si is transformed into crystalline Si having the (100)-normal crystallographic orientation in response to a first (one or more) laser scan, and completely melted Si is transformed into crystalline grains elongated in the first direction, in response to a second laser scan.

Additional details of the above-described method and a (100)-normal crystallographic orientation Si film structure with elongated crystal grains are provided below.

### BRIEF DESCRIPTION OF THE DRAWINGS

FIG. 1 is a partial cross-sectional view of a (100)-normal crystallographic orientation silicon (Si) film structure with elongated crystal grains.

FIG. 2 is a plan view of the structure of FIG. 1.

FIG. 3 is a partial cross-sectional view depicting a variation of the structure of FIG. 1.

FIGS. 4A through 4D are schematic views comparing various sample configurations, irradiation schemes, and resulting microstructures.

FIG. 5 is a flowchart illustrating a method for forming a directionally crystallized (100)-normal crystallographic orientation Si film.

### DETAILED DESCRIPTION

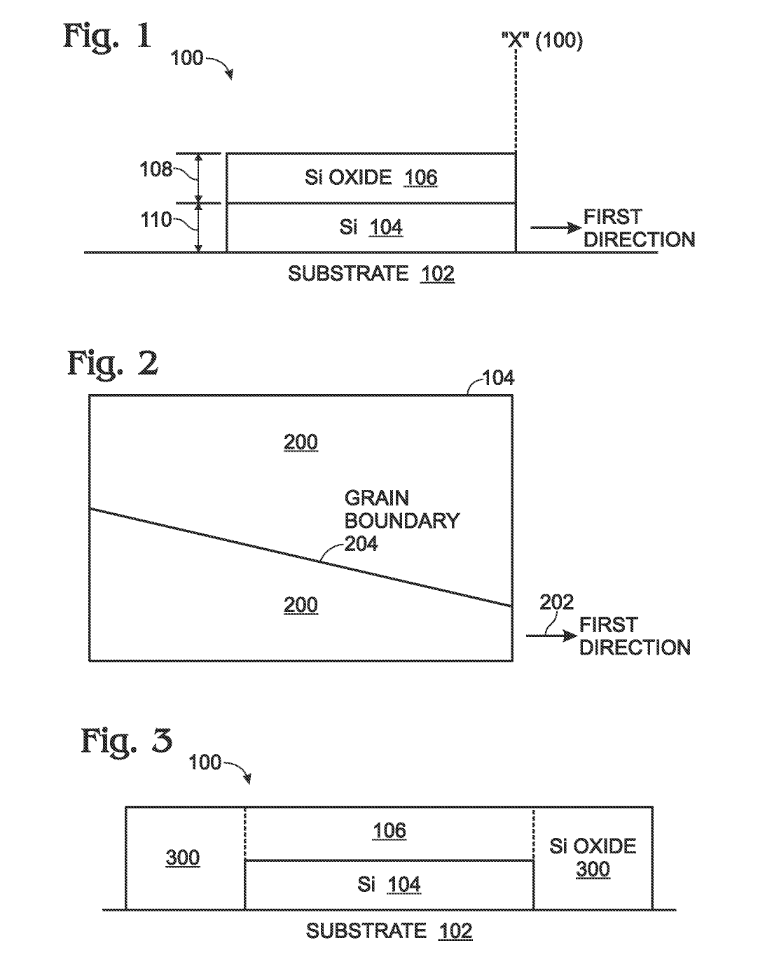

FIG. 1 is a partial cross-sectional view of a (100)-normal crystallographic orientation silicon (Si) film structure with elongated crystal grains. The structure 100 comprises a substrate 102 including Si. For example, the substrate 102 may be doped or undoped Si, silicon oxide, glass, silica, or silicon nitride. A crystalline Si film 104 overlies the substrate 102. The crystalline Si film 104 has a (100)-normal crystallographic orientation with crystal grains elongated in direction parallel to a top surface plane of the crystalline Si film. The structure 100 is shown sectioned in the “X” dimension. When discussing a single grain, it is appropriate to say that the grain has a certain “orientation.” When discussing a polycrystalline microstructure, it is not strictly correct to talk about its orientation; rather the term “texture” is more appropriate, which means that the orientations of the many grains tend to be aligned in some way [e.g., with (100) axes normal to the surface plane], statistically different from what would occur if their orientations were random.

FIG. 2 is a plan view of the structure of FIG. 1. In this view, the crystal grains 200 can be seen elongated in the first direction 202. The crystalline Si film 104 grain boundaries 204 between crystal grains 200, aligned in parallel with the first direction 202. More explicitly, the grains are approximately aligned. In some aspects, the grains may not be perfectly oriented; there is some angular range close to exact (100) normal, within 15°. Note: the crystalline Si film is shown without an overlying Si oxide layer.

Returning to FIG. 1, a silicon oxide cap layer 106 overlies the Si film 104. Typically, the silicon oxide cap layer 106 has a thickness 108 of greater than about 50 nanometers (nm). In some aspect, the crystalline Si film 104 has a thickness 110 of greater than about 50 nm. In one aspect, the Si film thickness 110 is 270 nm.

FIG. 3 is a partial cross-sectional view depicting a variation of the structure of FIG. 1. In this view, the crystalline Si film 104 includes pattern regions 300 exposing portions of the substrate 102. In addition to the silicon oxide cap layer 106 overlying the crystalline Si 104, the silicon oxide layer 106 fills the crystalline Si film pattern regions 300.

### Functional Description

The above-described structure and associated process described below stems from a phenomenon that was discovered somewhat by accident. In previous work using CW-laser scanning irradiation to crystallize a thin silicon film, polycrystalline film were created having equiaxed grains with an average size of approximately 4 microns (μm). The normal orientation was predominantly (100), but the in-plane was random. This process involved scanning the CW-laser across the film under conditions, such as a controlled scanning speed and laser power, such that the film undergoes near-complete melting in the irradiated zone. This process is sometimes referred to as a “mixed-phase ZMR (zone-melting recrystallization) regime”.

One problem with this scheme is that the equiaxed polycrystalline material has a degree of surface roughness that is detrimental to the performance of subsequently fabricated TFTs. Surface roughness in this case is usually localized along the grain boundary edges, in the form of sharp Si protrusions from the surface. TFTs fabricated on these areas exhibit low mobility due to Si surface defects and/or low reliability due to high gate current and similar high-field related failures.

In an attempt to suppress the formation of this surface roughness during crystallization, a cap oxide (SiO₂) layer was deposited over the silicon film. During crystallization, it was hoped that the presence of the cap oxide would constrain the molten silicon as it solidified and reduce the height of protrusions in the crystallized film. A reduction in roughness was observed as a result of the presence of the cap oxide. However, quite unexpectedly it was observed that in some instances the microstructure was directional (i.e., long, continuous grains extending in the scanning direction) rather than equiaxed.

The directionally solidified microstructure results from scanning crystallization when the laser conditions are such that complete melting occurs in the molten zone. When a Continuous Wave (CW)-laser is used for this process, it is called CW-laser Lateral Crystallization (CLC). Generally speaking, a pulsed laser such as an excimer can also be used to produce the directionally solidified microstructure, in which case the process is called “directional SLS (sequential lateral solidification).” CLC processes are well known in the art as demonstrated in the following references: (1) Hara, et al., AM-LCD01, p 227 (2001), (2) Takeuchi et al., AM-LCD01, p. 251 (2001), (3) Hara et al., IEDM'01 Tech. Digest, p 747(2001), and (4) Sasaki et al., SID 02 digest, p 154 (2002). These sources are incorporated herein by reference. Generally in the CLC process, a CW laser beam is formed into a shape approximating a line aspect, and scanned across a silicon film under conditions, such as beam power density and scanning speed, to effect complete melting of the film in the moving irradiated zone. Consequently, directional solidification occurs—ideally without causing damage to the underlying substrate, which for most applications of interest is glass. In CLC, the films usually do not have a cap oxide. That fact, the relatively high scan speeds that are used to maximize throughput lead to a random texture in the resulting directional microstructure (i.e., the grains do not have a preferred orientation).

As mentioned above, typically the process to produce (100)-oriented material is conducted under conditions that lead to less-than-complete (near-complete) melting of the film in the region of the beam. The presence of the cap oxide makes it difficult to assess the degree of melting, for example by evaluating test scans, because the cap oxide obscures the view of the crystallized silicon film. Therefore, when the cap oxide was removed and the crystallized films examined, it was found that in some cases, that quite accidentally complete-melting conditions had occurred with a resulting directionally crystallized microstructure. The surprising feature was that these directionally crystallized films had a predominantly (100)-normal preferred crystallographic orientation. Previously, such a preferred orientation had only been observed in films crystallized under the near-complete melting (“mixed-phase ZMR”) conditions, which does not give directionally solidified material. Furthermore, previous experiments had shown that when the mode of crystallization changed from near-complete melting to complete melting (directional), the (100) orientation was quickly lost. However, the previous experiments had been conducted on films that did not have a cap oxide.

It is believed that the presence of the cap oxide allows for directional crystallization with preferred (100)-normal crystallographic orientation—a previously unavailable combination. While the exact mechanism behind this phenomenon is not completely understood, it is believed that the surface energetics at the silicon-oxide interface is responsible for the formation of (100) preferred orientation for films crystallized in the mixed-phase ZMR regime. Silicon grains with a (100) orientation, sitting on a glass or fused silica substrate, are slightly more resistant to melting, under appropriate laser irradiation, than grains with other crystallographic orientations. When the film is almost completely, but not quite completely melted, those grains with (100) orientation are favored to survive at the expense of grains with other orientations. Subsequent to melting, the surviving grains regrow and are enlarged. Thus the film becomes enriched in (100)-oriented grains.

Mixed-phase ZMR (zone-melting recrystallization) is a term used to describe a process, very similar to CLC as described above, but wherein the laser scanning parameters are adjusted not to give complete melting of the film, but rather, near-complete melting. In this regime, the resulting film has an equiaxed microstructure (i.e., the grains have an aspect close to round) and a (100)-normal texture. That is, a large fraction of the grains have a (100) crystallographic axis oriented close to (e.g., within 15° of) the sample normal. Note that both processes (CLC and mixed-phase ZMR) fall within the category of ZMR (zone-melting recrystallization), which is a term for processes that involve recrystallizing a film by moving a narrow molten zone across the film. This technology dates back to the 1960s, and a considerable literature on the topic exists.

Normally, complete melting tends to destroy this (100) orientation. Even though the grains might have (100) orientation at the start of directional solidification [e.g., if a (100) texture is created by crystallizing in the mixed-phase ZMR regime, and the conditions are changed to switch to complete melting and directional solidification], such an orientation quickly is lost, after at most several microns of lateral growth, because the grain orientations rotate as the grains grow laterally. This has been observed repeatedly.

Apparently, the presence of the cap oxide, by eliminating the free surface of the molten silicon and effectively doubling the area of the silicon-oxide interface, allows lateral growth/directional solidification to proceed without a rotation of the grains' crystallographic orientations, and the (100)-normal orientation is maintained.

Good results were obtained with multiple scans of the film. It may be necessary for the first scan to create the (100) orientation under mixed-phase ZMR conditions and then one or more subsequent scans induce complete melting and (oriented) directional solidification. However, there is some evidence of oriented directional solidification in films that were scanned only once, so a single-scan process may be possible.

One further point worth mentioning is that the (100)-oriented directional microstructure obtained in this way was also found to have an exceptionally wide grain boundary spacing in the direction perpendicular to the scan direction. This wide boundary spacing is also a beneficial characteristic of the material as it effectively increases the grain size and reduces the concentration of grain boundaries.

The phenomenon of oriented lateral growth via scanning CW-laser irradiation of a silicon film with a cap oxide has not been fully explored. Table 1 presents results of the phenomenon for the following specific instances:

TABLE 1

| Silicon Film | Cap Oxide | Scanning |
|---|---|---|
| Thickness (nm) | Thickness (nm) | Speed (mm/s) |
| 66-67 | 50, 90, 990 | 50, 100 |
| 114 | 270 | 50 |

The directional growth effect seems stronger, generally, for thicker films (114 nm vs. 66 nm) and for thicker cap oxide (990 nm vs. 50 nm). However, the experimental space has not been systematically probed. The differences could be at least partially related to “accidental” differences, such as how deeply the scans were conducted (unintentionally) in the complete-melting regime. It becomes increasingly difficult to assess the true melting condition, which is usually done via simple visual examination under suitable magnification, as the cap oxide thickness increases. The cap oxide obscures the view of the crystallized film. Therefore, some alternate diagnostic method may be needed, such as the use of a probe laser.

Scanning speed may be an important parameter. Generally, better results were observed with slow scan speeds (50 and 100 mm/s). Experiments with scan speeds of 200 and 350 mm/s did not show such good results. This is consistent with previous experiments creating (100) texture under mixed-phase ZMR conditions. However, there is again the added factor that the melting condition cannot be precisely selected because of the cap oxide.

Also, there is a problem with agglomeration of the films underneath the cap oxide—particularly for thinner films and thicker cap oxides (>50 nm). The sporadic agglomeration interrupts the continuous directionally solidified grains, and may serve to introduce grains with non-(100) orientations. Some means of preventing agglomeration may be necessary to further development.

One variation of the process is patterning the silicon layer, and filling in areas where silicon is removed with SiO₂. Knowing that the presence of the covering cap oxide enhances the formation of a preferred (100)-normal orientation, compared with the case where the silicon is in contact with SiO₂ at the bottom interface only, increasing the silicon—SiO₂ contact area is believed to strengthen the effect. For example, the film may be patterned prior to crystallization, in some way that matches the locations of the active channels of the TFTs. As always, there would be an oxide layer underneath the silicon film. The areas where the silicon is removed via patterning is also be filled in with SiO₂, and everything is covered with a cap oxide. This structure maximizes the silicon-SiO₂ contact area during crystallization. Furthermore, reducing the lateral extent of the silicon may lead to enhancement of the directionally solidified microstructure by reducing the number of grain boundaries. This is because the grain boundaries tend to be eliminated by growing out to the edges when narrow regions of silicon are crystallized.

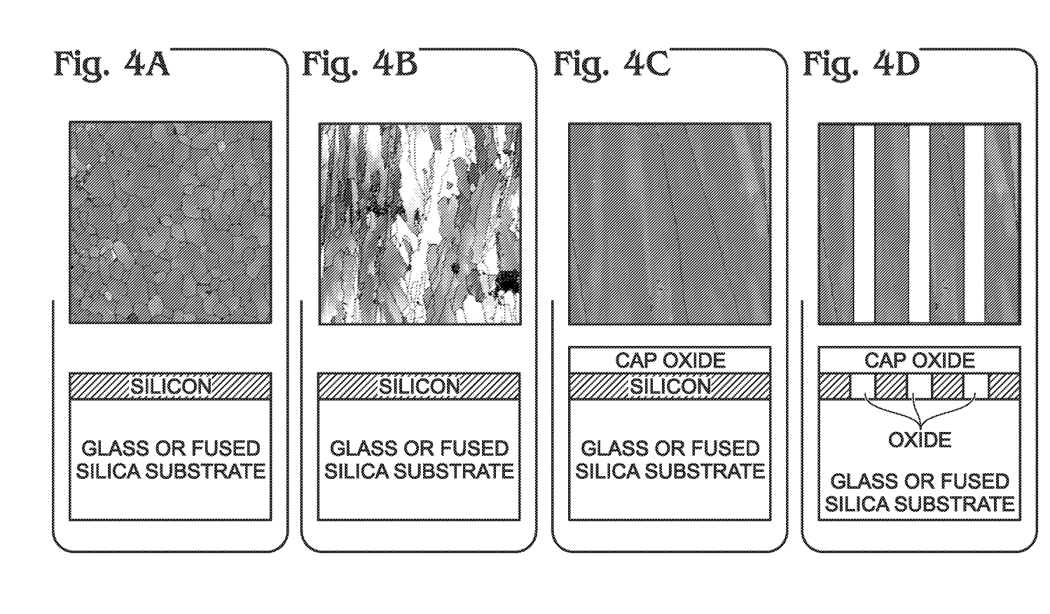

FIGS. 4A through 4D are schematic views comparing various sample configurations, irradiation schemes, and resulting microstructures. The top row is a top (plan) view, shaded to indicate normal crystallographic orientation as determined via Electron backscatter diffraction (EBSD). The bottom row is a partial cross-sectional view of various structures. In FIG. 4A, an uncapped sample is crystallized under near-complete melting (mixed-phase ZMR) conditions. The resulting polycrystalline microstructure has a preferred (100)-normal texture and equiaxed grains. In FIG. 4B an uncapped sample is crystallized in the complete-melting regime (CLC directional). The resulting directional microstructure has no preferred crystallographic orientation in the normal direction. In FIG. 4C a capped sample is crystallized under complete-melting conditions. The resulting directional microstructure maintains a preferred (100)-normal crystallographic orientation. Furthermore, the film has been found to have an exceptionally wide grain boundary spacing in the direction perpendicular to the scan. In FIG. 4D a patterned and capped film is crystallized under complete-melting conditions. The resulting microstructure in the patterned silicon has a preferred (100)-normal orientation and approaches single-crystal quality because the grain boundaries tend to be eliminated by running out to the edges of narrow regions of silicon as the film solidifies. FIGS. 4C and 4D are examples of crystallization performed in accordance with the processes described herein.

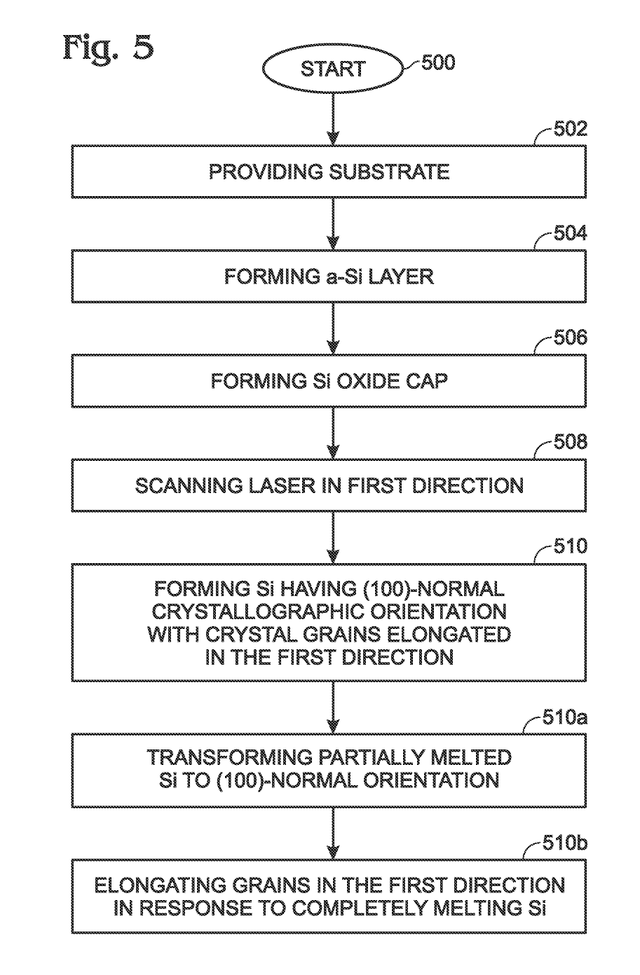

FIG. 5 is a flowchart illustrating a method for forming a directionally crystallized (100)-normal crystallographic orientation Si film. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 500.

Step 502 provides a substrate including Si, such as (pure) Si, silicon oxide, glass, silica, and similar Si-containing materials conventionally used in IC fabrication processes. Step 504 forms an amorphous Si (a-Si) layer overlying the substrate. For example, the a-Si film may be deposited using a chemical vapor deposition (CVD) process. However, other processes of forming an a-Si film are widely known in the art, which would enable the method of FIG. 5. In one aspect, the a-Si film has a thickness of greater than 50 nm. Step 506 forms a silicon oxide cap layer overlying the a-Si layer. For example, the silicon oxide may be deposited, or the a-Si layer may be oxidized. In one aspect, the silicon oxide cap layer may have a thickness of greater than 50 nm. Step 508 scans a laser in a first direction along a top surface of the silicon oxide cap layer. Step 510 transforms the a-Si layer in response to laser annealing, into a crystalline Si film having a (100)-normal crystallographic orientation, with crystal grains elongated in the first direction. That is, Step 510 forms grain boundaries between crystal grains, aligned in parallel with the first direction.

In one aspect, forming the a-Si layer in Step 504 includes forming an a-Si layer with pattern regions exposing portions of the substrate. Then, forming the silicon oxide cap layer overlying the a-Si layer in Step 506 additionally includes forming silicon oxide in the a-Si layer pattern regions. Note: the silicon oxide cap layer and the silicon oxide covering the pattern regions may be formed simultaneously, or in separate process steps.

In one aspect, transforming the a-Si layer into the crystalline Si film in Step 510 includes completely melting the Si in response to laser annealing. As an alternative, scanning the laser in Step 508 may include performing a plurality of laser scans. Then, transforming the a-Si layer into the crystalline Si film in Step 510 includes substeps. Step 510a transforms partially melted Si to crystalline Si having the (100)-normal crystallographic orientation in response to a first laser scan. Note: partially melting may occur as a result of one or more laser scans. Step 510b transforms completely melted Si into crystalline grains elongated in the first direction, in response to a second laser scan. Again, the second laser scan may represent one or more actual laser scans.

In another aspect, Step 508 laser scans using a Continuous-Wave (CW) laser. For example, the laser may be scanned at a rate in the range of about 50 to 100 mm per second. As another example, the silicon oxide cap layer formed in Step 504 may have a thickness of about 265 nm, and the scanning performed with a laser having a wavelength of about 532 nm.

A method has been presented for forming a directionally annealed (100)-normal crystallographic orientation Si film. Examples of process details and structures have been given to illustrate the invention. However, the invention is not necessarily limited to these examples. Although Si films have been described in detail, the processes described herein are relevant to other semiconductor materials. Other variations and embodiments of the invention will occur to those skilled in the art.

We claim:

1. A method for forming a directionally crystallized (100)-normal crystallographic orientation silicon (Si) film, the method comprising:
providing a substrate including Si;
forming an amorphous Si (a-Si) layer overlying the substrate;
forming a silicon oxide cap layer overlying the a-Si layer;
scanning a laser in a first direction along a top surface of the silicon oxide cap layer; and,
transforming the a-Si layer in response to laser annealing, into a crystalline Si film having a (100)-normal crystallographic orientation, with crystal grains elongated in the first direction.

2. The method of claim 1 wherein transforming the a-Si layer into the crystalline Si film includes forming grain boundaries between crystal grains, aligned in parallel with the first direction.

3. The method of claim 1 wherein forming the a-Si layer includes forming an a-Si layer with pattern regions exposing portions of the substrate; and,
wherein forming the silicon oxide cap layer overlying the a-Si layer additionally includes forming silicon oxide in the a-Si layer pattern regions.

4. The method of claim 1 wherein transforming the a-Si layer into the crystalline Si film includes completely melting the Si in response to laser annealing.

5. The method of claim 1 wherein scanning the laser includes performing a plurality of laser scans; and,
wherein transforming the a-Si layer into the crystalline Si film includes:
transforming partially melted Si to crystalline Si having the (100)-normal crystallographic orientation in response to a first laser scan; and,
transforming completely melted Si into crystalline grains elongated in the first direction, in response to a second laser scan.

6. The method of claim 1 wherein scanning the laser includes scanning with a Continuous-Wave (CW) laser.

7. The method of claim 1 wherein scanning the laser includes scanning at a rate in a range of about 50 to 100 mm per second.

8. The method of claim 1 wherein forming the a-Si layer includes forming an a-Si layer having a thickness of greater than about 50 nanometers (nm).

9. The method of claim 1 wherein forming the silicon oxide cap layer includes forming a silicon oxide layer having a thickness of greater than about 50 nm.

10. The method of claim 1 wherein scanning the laser includes scanning a laser having a wavelength of about 532 nm; and,
wherein forming the silicon oxide cap layer includes forming a silicon oxide layer having a thickness of about 265 nm.

11-16. (canceled)
